(19) United States
(12) Patent Application Publication
(10) Pub. No.: US 2005/0219923 A1
(43) Pub. Date: Oct. 6, 2005

(54) EEPROM and method of testing same

(75) Inventor: Johan Eneland, Kungsangen (SE)

Correspondence Address: LAUBSCHER SEVERSON, 1160 SPA RD, SUITE 2B, ANNAPOLIS, MD, 21403, US

(73) Assignee: Zarlink Semiconductor AB, Jarfalla (SE)

(21) Appl. No.: 11/089,593

(22) Filed: Mar. 25, 2005

(30) Foreign Application Priority Data
Mar. 26, 2004 (GB) 0406812.8

(51) Int. Cl. G11C 29/00

(52) U.S. Cl. 365/201

(57) ABSTRACT

An EEPROM consists of a plurality of cells, each including a pair of transistors. An extra select transistor is provided in each of said cells for selecting a predetermined state for that cell in response to an input signal.

### FIELD OF THE INVENTION

This invention relates to the field of electronically erasable programmable read-only-memories (EEPROMs), and in particular to novel EEPROMs and a novel method of testing such EEPROMs.

### BACKGROUND OF THE INVENTION

EEPROMs are used in a wide variety of electronic applications. They provide non-volatile memories that can, for example, store programs that can be updated by rewriting the date in the EEPROM. For example, they allow a user to update the bios in a computer. However, before EEPROMs can be sold, they must be tested to ensure that they function correctly. It can take a relatively long time to test EEPROMs, for example five seconds or more. A long test time of course translates into a high production cost when account is taken of mass production.

In order to test EEPROMs multiple read and write operations must be carried out in order to test each possible bit pattern. It is the write operations that are very slow and as a result they dominate the overall test time. In order to decrease the test time, it is possible to compromise on the number of operations, but such compromises decrease the quality of the test and offer low fault coverage, especially on the address logic.

FIG. 1 shows two prior art EEPROM cells, each of which consists of two transistors and a capacitor. To write unique data on each address requires a large number of write operations. At least two write operations to each address is needed in order to check that both 0 and 1 can be written to each bit in the EEPROM. To check for failures in the address logic even more write operations are needed.

### SUMMARY OF THE INVENTION

The invention proposes a method of reducing the test time in EEPROM memories by a magnitude 100× or more, and at the same time allowing increased quality of testing. The trade-off for this reduction in test time is the use of extra chip real estate. The real estate required for a 1s test of a novel EEPROM amounts to approximately 0.7-0.8 mm² of the silicon area.

According to a first aspect of the invention there is provided an EEPROM comprising a plurality of cells, each including a first and second transistor; a bit line for each cell; and an extra select transistor in each of said cells for selecting a predetermined state for that cell in response to an input signal.

According to a second aspect of the invention there is provided a method of testing an EEPROM comprising applying a write pulse to each cell over a write test data line; and applying a first binary state to each bit line and a second binary state to a test bit line such that each cell enters a state determined by an extra select transistor in that cell to write a unique pattern to the entire EEPROM in one write operation.

One test method commonly employed for testing memories is known as a common march algorithm. In such algorithms for every word must be written several times in order to cover all the address logic. In the novel solution in accordance with the invention it is sufficient to perform two write operations. It is then possible to confirm that both 0 and 1 can be written and read from each cell and that data is read from correct address.

The dramatic reduction in the number of write operations required results in a substantial reduction in the time required to test a chip. For a given test quality, the test time will typically be approximately 100× faster than the prior art, or for a given test time the test quality will be much higher.

### BRIEF DESCRIPTION OF THE DRAWINGS

The invention will now be described in more detail, by way of example only, with reference to the accompanying drawings, in which:

FIG. 1 is a schematic diagram showing two EEPROM in accordance with the prior art; and

FIG. 2 is a schematic diagram of part of an EEPROM in accordance with one embodiment of the invention.

### DETAILED DESCRIPTION OF THE PREFERRED EMBODIMENTS

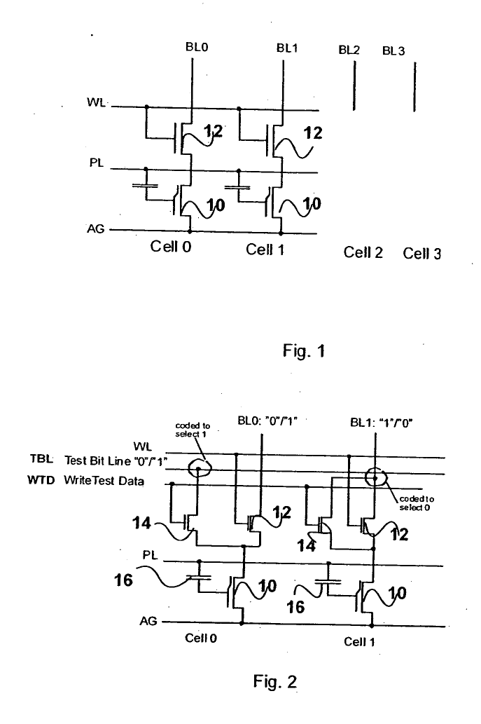

The part of an EEPROM shown in FIG. 1 comprises a plurality of cells, Cell 0, Cell 1, Cell n . . . , each consisting of two transistors 10, 12 and a capacitor 16. The EEPROM includes bit lines BL0, BL1 . . . , a write line WL, and lines PL and AG whose function is conventional.

In accordance with an embodiment of the invention illustrated in FIG. 2, each cell is provided with an additional transistor 14 having one electrode connected to an extra test bit line TBL or bit line BL and its gate connected to a write test data line WTD.

With help of this one extra select transistor per EEPROM-cell it is possible to write a unique test pattern to all words. The extra select transistor 14 is hard coded to 0 or 1. For example, when a write pulse is applied to the line WTL (WriteTestData), if Cell 0 is programmed to write a “1”, cell 1 is programmed to write a “0” and so on. A unique pattern is therefore written to each word in the EEPROM in only one write operation. A global test write operation writes a unique data pattern to all words.

In one embodiment, the actual address of each memory location is as data at that address. This works well as the long word length is longer than the address. However, if the address field is larger than the word length, it may still be possible to write unique data to all words in a column of the EEPROM.

To write data to the EEPROM, a 1 is applied line BL, 0 to line TBL and a write pulse is applied to line TBL. To write inverse data on the EEPROM, it is merely necessary to invert the signals on the bit lines BL. A binary 0 is applied to line BL and a binary is applied to line TBL.

The net cost of this is one extra select transistor per memory cell, two extra signals, one signal for select of test pattern, and one signal for the inverse value of BL. The Bit Line BL can be used in “test write” mode. The extra wires can be used by adjacent cells.

### EXAMPLE OF A TEST ALGORITHM IN ACCORDANCE WITH AN EMBODIMENT OF THE INVENTION

Step 1: perform global test write unique pattern to each word (write operation 1)

Step 2: perform read and check pattern from all addresses, (for example incrementing addresses)

Step 3: perform global write inverse pattern to each word (write operation 2)

Step 4: perform read and check inverse pattern from all addresses, (for example decrementing addresses)

This algorithm checks that 0 and 1 can be written and read from every cell. It also confirms that every word is addressed correctly during a read operation. The same address logic is used for write operations.

### COMPARATIVE EXAMPLES

The manner in which the extra transistor permits time to be saved will be more clearly understood from the following illustration. Consider a small EEPROM capable of storing four words with eight bits per word. Each bit position needs to be tested with both 0 and 1. In addition the address decoding logic should be tested.

For a conventional EEPROM, the following actions must be performed:
Write address 0 data=0
Write address 1 data=1
Write address 2 data=2
Write address 3 data=3
Read address 0 and check that data=0
Read address 1 and check that data=1
Read address 2 and check that data=2
Read address 3 and check that data=3
Write address 0 data=complement of 0=hexadecimal FF
Write address 1 data=complement of 1=hexadecimal FE
Write address 2 data=complement of 2=hexadecimal FD
Write address 3 data=complement of 3=hexadecimal FC
Read address 3 and check that data=hexadecimal FC
Read address 2 and check that data=hexadecimal FD
Read address 1 and check that data=hexadecimal FE
Read address 0 and check that data=hexadecimal FF

This operation requires eight write operations and eight read operations.

Consider now an EEPROM with extra test logic in accordance with the embodiments of the invention. The following operation is performed:

Write the whole EEPROM with the programmed pattern (address 0 data=0, address 1 data=1, address 2 data=2, address 3 data=3 etc.).
Read address 0 and check that data=0
Read address 1 and check that data=1
Read address 2 and check that data=2
Read address 3 and check that data=3
Write the whole EEPROM with the programmed pattern inverted
(address 0, data=complement of 0=hexadecimal FF
address 1, data=complement of 1=hexadecimal FE
address 2, data=complement of 2=hexadecimal FD
address 3, data=complement of 3=hexadecimal FC)
Read address 3 and check that data=hexadecimal FC
Read address 2 and check that data=hexadecimal FD
Read address 1 and check that data=hexadecimal FE
Read address 0 and check that data hexadecimal FF

This operation requires two write operations and eight read operations. The write cycle is much larger than the read cycle. The saving of test time is proportional to the number of words in the EEPROM. If the EEPROM has 128 words the saving of write time will be 128 times.

It will thus be seen that the extra transistor and control wires in each cell make it possible to write the chosen pattern or bit wise inverse pattern to the whole EEPROM in one cycle, resulting in a considerable saving in time.

The area of the memory cells will be larger. In for example Gulp's EEPROM, the memory array is approximately 50% of the EEPROM area. The other logic will be almost the same. If the memory cell area is, for example 30% larger, the EEPROM will be 15% larger. The small increase in memory area is a small price to pay for the shorter test time/cost. The minor changes in area will have a marginal influence on power consumption.

The following table compares the prior art with an embodiment of the present invention.

| | | With extra select |
|---|---|---|
| | Prior Art | transistor |
| Area | x | larger |
| Development cost | 0 | “high” |
| Test time | long | much shorter |
| | | (approx 100X) |
| Fault coverage. | | higher |
| Quality. | | higher |
| Power | y | y |

The above comparison is made for the “same” test quality, (unique pattern is written in each word, write and read of both 0 and 1 in each cell tested).

A prior art 256 word EEPROM required 256 words, 2*256 write operations, and 2*256 read operations. The test time for writing the EEPROM was approximately 5s. With the help of a page write it can be reduced to approx 1.3 s. With an extra transistor in accordance with an embodiment of the invention, only two write operations and 2*256 read operations are required. The test time for writing the EEPROM is approximately 20 ms. The write cycle is 10 ms. This represents a considerable improvement over the prior art.

1. An EEPROM comprising:
a plurality of cells, each including a first and second transistor;
a bit line for each cell; and
an extra select transistor in each of said cells for selecting a predetermined state for that cell in response to an input signal.

2. An EEPROM as claimed in claim 1, further comprising a test bit line, and wherein each said extra select transistor is connected either to said bit line or said test bit line.

3. An EEPROM as claimed in claim 2, further comprising a write test data line, and wherein each said select transistor is also connected to said write test data line, whereby a test bit line signal and a test write data signal is distributed to all cells.

4. An EEPROM as claimed in claim 3, wherein each said select transistor is connected to said write test data line through a gate thereof.

5. An EEPROM as claimed in claim 3, wherein the extra select transistor is configured such that test data written to each cell is unique for each word.

6. An EEPROM as claimed in claim 5, wherein the extra select transistor is configured so that when the bit lines are set to 0, and the test bit line is set to 1, a first test pattern is written to the entire EEPROM in a single write operation.

7. An EEPROM as claimed in claim 6, wherein the extra select transistor is configured so that when the states of said bit lines and said test bit line are inverted, a bitwise complement pattern is written to the entire EEPROM in a single write operation.

8. A method of testing an EEPROM comprising:
applying a write pulse to each cell over a write test data line; and
applying a first binary state to each bit line and a second binary state to a test bit line such that each cell enters a state determined by an extra select transistor in that cell to write a unique pattern to the entire EEPROM in one write operation.

9. A method as claimed in claim 8, wherein after applying said first and second binary states, said pattern is read and checked for each address in said EEPROM.

10. A method as claimed in claim 9, wherein the binary state of applied to each bit line and to said test bit line is reversed so as to write a bitwise complement pattern into the entire EEPROM.

11. A method as claimed in claim 11, wherein said bitwise complement pattern is read and checked for each address in the entire EEPROM.

12. A method as claimed in claim 8, wherein in said unique pattern the address of each memory location is written as test data to that memory location.
